(19) United States
(12) Patent Application Publication
(10) Pub. No.: US 2025/0066649 A1
(43) Pub. Date: Feb. 27, 2025

(54) PHOTOPOLYMERIZABLE ADHESIVE COMPOSITION FOR ENCAPSULATING ELECTRONIC OR OPTOELECTRONIC DEVICES

(71) Applicants: ARKEMA FRANCE, Colombes (FR); COMMISSARIAT A L'ENERGIE ATOMIQUE ET AUX ENERGIES, PARIS (FR)

(72) Inventors: Stéphane CROS, Grenoble (FR); Céline LABARTHE, Lacq (FR); Christian LAURICHESSE, Lacq (FR); Mathis MAJOREL, Grenoble (FR)

(21) Appl. No.: 18/723,324

(22) PCT Filed: Dec. 22, 2022
(86) PCT No.: PCT/EP2022/087431

§ 371 Date: Jun. 21, 2024

(30) Foreign Application Priority Data
Dec. 22, 2021 (FR) 2114208

(51) Int. Cl. C09J 133/12; C09J 4/06; H10K 30/88

(52) U.S. Cl. CPC C09J 133/12; C09J 4/06; H10K 30/88; C09J 2433/00; C09J 2453/00

(57) ABSTRACT

The present invention relates to photopolymerizable adhesive compositions used in the encapsulation of electronic and optoelectronic devices, in particular flexible electronic and optoelectronic devices, for example photovoltaic cells, in order to protect them against gas and moisture permeation.

### FIELD OF THE INVENTION

The present invention relates to photopolymerizable adhesive compositions used to encapsulate electronic and optoelectronic devices, in particular flexible electronic and optoelectronic devices, for example organic photovoltaic cells for protection thereof against gas and moisture ingress.

### TECHNICAL BACKGROUND

There exist different types of electronic or optoelectronic devices, in particular rigid or flexible electronic or optoelectronic devices.

Rigid electronic and optoelectronic devices may be of different types according to the applications under consideration, such as display (e.g. OLEDs and QLEDs), photovoltaic (e.g. silicon semiconductors, CIGS cells, CdTe cells, organic semiconductors, semiconductors of perovskite type), or sensors.

Flexible electronic and optoelectronic devices may be defined according to the same examples of application, but for semiconductor technologies compatible with the use of flexible substrates such as an organic light-emitting diodes (OLEDs), organic photovoltaic cells (OPVs), amorphous silicon cells (a-Si), CIGS cells, semiconductors of perovskite type, organic field-effect transistors (OFETs) or organic sensors using organic semiconductors.

Electronic and optoelectronic devices are devices sensitive to multiple factors, for example to light, heat, oxygen (air), moisture, pressure, impact, etc. To ensure optimal efficacy and yield and to obtain satisfactory durability, they must therefore be protected and isolated from their environment. This protection must be all the more efficient when the constituent materials are sensitive to the atmosphere, in particular to water and oxygen. This is particularly the case with the use of organic semiconductors, for example semiconductors of perovskite type or CIGS semiconductors.

Different encapsulation techniques have been developed. These generally comprise coating the device with an adhesive composition to obtain a coated device, then laminating the coated device between two barrier layers to obtain an encapsulated device. The choice of adhesive composition and barrier layer will depend upon the devices to be encapsulated. In addition, as a function of the composition and the barrier layers used, the electronic or optoelectronic modules obtained will have specific properties, in particular in terms of weight, thickness, transparency/opacity, rigidity/flexibility, permeability/sealing against gases and liquids, impact strength/durability/resistance to ageing.

Having regard to the arrangement in the form of layers, two types of permeation may be observed: orthogonal permeation at the outer surface of the barrier layers between which the coated devices are intercalated, and lateral permeation at the free edge of the adhesive within the coating material and at the interface between the two barrier layers.

Protection of the device against lateral permeation is particularly ensured by the adhesive or coating material the efficacy of which may depend on different factors, in particular the chemical formulation, method of application, thickness thereof (proportional to the exchange surface with the environment), the interface thereof with the barrier layers, resistance to operational stresses, etc. The properties of the adhesive must therefore be optimized to minimize and even eliminate lateral permeation, to ensure optimal efficacy and yield and to obtain satisfactory durability.

Flexible photovoltaic cells (e.g. organic, perovskite, CIGS, CdTe cells) represent an alternative of particular interest to silicon-based rigid photovoltaic cells in that they may be produced at high production rates with continuous processes (roll-to-roll process) and may be suitable for applications requiring flexibility, conformability or of lightweight. They are also less fragile (use of flexible barrier layers) and less sensitive to breakage.

Flexible photovoltaic cells may be obtained for example by low temperature printing of an active thin layer (organic or perovskite material having semiconductor properties) deposited on a supporting flexible polymer substrate.

Encapsulation of a flexible electronic or optoelectronic device may be obtained for example by means of a barrier layer scarcely permeable to gases and in particular to water vapour and to oxygen, which must be at least as flexible as the device it protects so that it does not become a factor limiting the flexing thereof, or it must have controlled flexibility when for example encapsulation is deliberately used to limit the radius of curvature of the device to prevent damage thereto.

There is therefore a true need to provide an adhesive composition allowing electronic or optoelectronic modules to be obtained having satisfactory properties, in particular satisfactory adhesive, optical, thermal, electrical, gas-barrier, elastic and strength properties. There is also a need to provide an adhesive composition adapted to the encapsulating of flexible electronic or optoelectronic devices. There is a further need to provide an adhesive composition allowing the obtaining of electronic or optoelectronic modules having time-limited photo-ageing (e.g. yellowing). There is also a need to provide an adhesive composition allowing the obtaining of electronic or optoelectronic modules having time-limited lateral permeation of gases and water. There is also a need to provide an adhesive composition allowing the obtaining of electronic or optoelectronic modules ensuring optimal efficacy and yield and having satisfactory durability.

### SUMMARY OF THE INVENTION

In a first aspect, the invention relates to a photopolymerizable adhesive composition comprising, by weight relative to the total weight of the photopolymerizable adhesive composition:
20 to 35% of at least one block copolymer, preferably a (meth)acrylic block copolymer;
45 to 75% of at least one (meth)acrylate monomer having a glass transition temperature (Tg) of at least 85° C.;
2 to 15% of at least one alkoxysilane (meth)acrylate monomer; and
0.1 to 5% of at least one photoinitiator.

In some embodiments, the block copolymer is chosen from the group consisting of block copolymers comprising at least one block M and at least one block B; said block M designating a block polymer comprising at least 50 weight % of methyl methacrylate; and block B designating an elastomer block polymer incompatible with block M and having a glass transition temperature lower than 20° C.

In some embodiments, the (meth)acrylate monomer having a glass transition temperature of at least 85° C. is chosen from the group consisting of methyl methacrylate, tert-butyl methacrylate, phenyl-methacrylate, isopropyl methacrylate, isobornyl methacrylate, isobornyl acrylate, cyclohexyl methacrylate, 4-ter-butylcyclohexyl methacrylate, dihydrodicyclopentadienyl acrylate, and mixtures thereof.

In some embodiments, the alkoxysilane (meth)acrylate monomer is chosen from the group consisting of trialkoxysilane (meth)acrylate monomers.

In some embodiments, the photopolymerizable adhesive composition also comprises at least one (meth)acrylate monomer having a glass transition temperature lower than 0° C., a methacrylic acid monomer, at least one urethane (meth)acrylate oligomer, at least one reactive monofunctional diluent, and mixtures thereof, I

In some embodiments, the (meth)acrylate monomer having a glass transition temperature lower than 0° C., if included, is chosen from the group consisting of butyl acrylate, ethyl acrylate, propyl acrylate, hexyl acrylate, octyl acrylate, dodecyl acrylate, isopropyl acrylate, isobutyl acrylate, isodecyl acrylate, 2-ethylhexyl acrylate, 2-propylheptyl acrylate, isodecyl methacrylate, dodecyl methacrylate, 2-hydroxyethyl acrylate, and mixtures thereof.

In some embodiments, the photopolymerizable adhesive composition is advantageously a one-component composition.

In some embodiments, the photopolymerizable adhesive composition has a glass transition temperature of at least 85° C., preferably of at least 90° C., more preferably of at least 100° C.

In a second aspect, the invention relates to an adhesive product comprising the photopolymerizable adhesive composition such as described in the foregoing and an opaque container in which it is contained.

In a third aspect, the invention relates to an adhesive obtained with the method comprising the following steps:
applying a photopolymerizable adhesive composition such as described above onto at least one barrier layer and/or electronic or optoelectronic device;
photopolymerizing the applied photopolymerizable adhesive composition to obtain a polymerized adhesive; and
optionally, forming the polymerized adhesive.

In a fourth aspect, the invention relates to an electronic or optoelectronic module comprising the assembly of a series of layers comprising in this order:
a first barrier layer;
a first adhesive such as described above or obtained from the photopolymerizable adhesive composition such as described above;
a flexible electronic or optoelectronic device;
a second adhesive such as described above or obtained from the polymerizable adhesive composition such as described above; and
a second barrier layer.

In some embodiments, the flexible electronic or optoelectronic device is chosen from among organic light-emitting diodes, organic photovoltaic cells, organic transistors, or organic sensors.

In some embodiments, the flexible electronic or optoelectronic device is a device of perovskite type.

In a fifth aspect, the invention relates to a method for obtaining the module such as described above, the method comprising the following steps:
providing an electronic or optoelectronic device;
providing a photopolymerizable adhesive composition such as described above;
providing a first barrier layer;
providing a second barrier layer;
applying layers of photopolymerizable adhesive composition to the surface of the device and/or to the respective inner surfaces of the first and second barrier layers;
laminating the device and layers of photopolymerizable adhesive composition between the respective inner surfaces of the first and second barrier layers; and
photopolymerizing the layers of photopolymerizable adhesive composition.

In a sixth aspect, the invention relates the use of the photopolymerizable adhesive composition such as described above, or of the adhesive such as described above, for the encapsulation of flexible electronic or optoelectronic devices.

The inventors have surprisingly shown that the photopolymerizable adhesive composition of the present invention, after application and photopolymerization, exhibits fully satisfactory even excellent properties, and in particular adhesive, optical, thermal, electrical, barrier, elastic and strength properties.

In addition, the invention also has one or preferably more of the following advantages:
obtaining electronic or optoelectronic modules having satisfactory properties, in particular satisfactory adhesive, thermal, optical, electrical, gas-barrier, elastic and strength properties;
satisfactory encapsulation of flexible electronic or optoelectronic devices;
obtaining electronic or optoelectronic modules having time-limited photo-ageing (e.g. yellowing);
obtaining electronic or optoelectronic modules having time-limited lateral gas and water permeation; and
obtaining electronic or optoelectronic modules ensuring optimal efficacy and yield and having satisfactory durability.

### BRIEF DESCRIPTION OF THE FIGURES

FIG. 1 gives the corresponding photographs and images obtained after computer analysis of the modules tested at Test 1.

FIG. 2 is a graph showing the degradation rate of the modules tested at Test 1.

FIG. 3 gives photographs of the modules tested at Test 2.

FIG. 4 is a graph showing percentage transmittance of the tested modules as a function of wavelength (nm) at Test 3.

### DETAILED DESCRIPTION

The invention is now described in more detail in the following nonlimiting description.

By “flexible” or “pliable”, it is meant the ability of a material, in particular on account of the intrinsic properties and/or narrow thickness thereof, to flex, bend and/or fold easily.

By “flexible electronic or optoelectronic device” (and the module obtained therefrom), it is meant a device (module) maintaining its electronic conductive or semiconductive properties even when bent with a very narrow radius of curvature without risk of buckling or delamination of the electronic components.

By “adhesive”, it is meant the matrix/structure formed around the electronic or optoelectronic device by the photopolymerized adhesive composition. The terms “adhesive” or “encapsulant” are interchangeably used herein.

By “module”, it is meant the assembly of the electronic or optoelectronic device coated with the polymerized adhesive composition and intercalated between the two barrier layers.

By “barrier layer”, it is meant the elements between which the coated electronic or optoelectronic device is laminated. Herein, this element may indifferently be called “substrate” “film” or “sheet”.

By “photopolymerizable composition” or “photo-crosslinkable composition”, it is meant a composition for which initiation of polymerization is triggered by exposure to electromagnetic radiation, in particular to ultraviolet radiation (UV).

By “photopolymerizable adhesive composition”, it is advantageously meant a composition developing adhesive properties when subjected to electromagnetic radiation, in particular to ultraviolet radiation (UV) which initiates polymerization thereof.

By “monomer” it is meant a molecule able to undergo polymerization. When the term “monomer” is used to designate a constituent of a polymer, this means the unit (or residue) derived from the monomer—or monomer unit/monomeric unit—via polymerization with at least one other monomer.

By “polymerization”, it is meant a process of converting a single type of monomers or mixture of different types of monomers to a polymer.

By “polymer”, it is meant a copolymer or homopolymer.

By “homopolymer”, it is meant a polymer grouping together several identical monomer units.

By “copolymer”, it is meant a polymer grouping together at least two types of different monomer units (called co-monomers).

By “oligomer” it is meant a polymer compound of small size obtained by polymerizing 2 to 30 monomers (comprising 2 to 30 monomer units) i.e. of which the degree of polymerization is between 2 and 30.

By “block copolymer”, it is meant a polymer comprising one or more non-interrupted sequences of each of the different polymer species, the polymer sequences chemically differing from each other and being linked together by a covalent bond. These polymer sequences are also called block polymers.

By “(meth)acrylic” (or “(meth)acrylate”), it is meant any type of acrylic and/or methacrylic (or acrylate and/or methacrylate) compounds, polymers, monomers or oligomers.

For example, (meth)acrylic acid designates acrylic acid or methacrylic acid, isobornyl (meth)acrylate designates isobornyl acrylate or isobornyl methacrylate, etc.

By “polymerization”, it is meant a chemical process allowing the bonding together of molecules to form a three-dimensional network.

By “initiator”, it is meant a chemical species which reacts with a monomer to form an intermediate compound capable of successfully binding to a large number of other monomers to form a polymer, or which reacts with polymers to initiate the process of molecular interconnection known as polymerization.

By “Tg”, it is meant the glass transition temperature. The glass transition temperature may be measured by differential scanning calorimetry (DSC), for example using the half-height tangent method measured between two points of inflection at the third heating cycle at between 4° and 140° C.

By “ambient temperature”, it is meant a temperature of about 20° C.

By “substantially free of”, it is meant a composition comprising less than 1%, preferably less than 0.1%, more preferably less than 0.01%, most preferably about 0% of a compound by weight relative to the total weight of the composition.

### Photopolymerizable Adhesive Composition

In a first aspect, the present invention relates to a photopolymerizable adhesive composition.

### Block Copolymer

The composition comprises at least one block copolymer, preferably at least one (meth)acrylic block copolymer.

The composition may comprise from 20 to 35%, preferably 25 to 30% of at least one block copolymer, by weight per total weight of the composition. The composition for example may comprise from 20 to 21%, alternatively from 21 to 22%, alternatively 22 to 23 00 alternatively 23 to 24%, alternatively 24 to 25%, alternatively 25 to 26%, alternatively 26 to 27%, alternatively 27 to 28%, alternatively 28 to 29%, alternatively 29 to 30%, alternatively 30 to 31%, alternatively 31 to 32%, alternatively 32 to 33%, alternatively 33 to 34%, alternatively 34 to 35% of at least one block copolymer by weight per total weight of the composition.

By “(meth)acrylic block copolymer”, it is meant a (meth)acrylic block copolymer comprising 10% or less (e.g. 0.1 to 10%), preferably 5% or less (e.g., 0.1 to 5%) of at least one non-(meth)acrylic monomer by weight per total weight of the copolymer. The non-(meth)acrylic monomer may be chosen from the group consisting of butadiene, isoprene, styrene, vinylnaphthalene, a cyclosiloxane monomer, vinylpyridine and derivatives thereof (e.g., a-methylstyrene or tert-butylstyrene).

The block copolymer may be chosen from among block copolymers comprising at least one block M and at least one block B, in particular block copolymers having the diblock structure B-M (or B-M diblock copolymer), or the triblock structure M-B-M (or M-B-M triblock copolymer) wherein each block is linked to the other by a covalent bond or by an intermediate molecule linked to one of the blocks by a covalent bond and to the other block by a covalent bond. The block copolymer is preferably a triblock M-B-M copolymer.

Block M designates a block polymer comprising at least 50 weight % of methyl methacrylate. Block M may designate a homopolymer block of poly(methyl methacrylate) (PMMA—100 weight % methyl methacrylate) or a block copolymer comprising at least 50 weight % of methyl methacrylate and 50 weight % or less of another monomer differing from methyl methacrylate, relative to the total weight of block M.

Block B designates an elastomer block polymer incompatible with block M and having a glass transition temperature (Tg) lower than ambient temperature, preferably lower than 0° C., more preferably lower than −20° C.

In the B-M diblock copolymer, block M may be consisting of monomers of methyl methacrylate. Alternatively, block M may comprise at least 50% (e.g. 50 to 99.9%), preferably at least 75% (e.g. 75 to 99.9%) of methyl methacrylate; and 50% or less (e.g. 0.1 to 25%), preferably 25% or less (e.g. 0.1 to 25%) of at least one other monomer differing from methyl methacrylate, by weight of the total weight of block M.

The other monomer differing from methyl methacrylate in block M may be another (meth)acrylic monomer or a non-(meth)acrylic monomer.

The non-(meth)acrylic monomer may be chosen from the group consisting of butadiene, isoprene, styrene, vinylnaphthalene, a cyclosiloxane monomer, vinylpyridine and derivatives thereof (e.g. a-methylstyrene or tert-butylstyrene).

The other (meth)acrylic monomer may be chosen from the group consisting of methyl acrylate, ethyl (meth)acrylate, (meth)acrylic acid, propyl (meth)acrylate, n-butyl (meth)acrylate, isobutyl (meth)acrylate, pentyl (meth)acrylate, hexyl (meth)acrylate, cyclohexyl (meth)acrylate, isobornyl (meth)acrylate, amides derived from (meth)acrylic acid (e.g. N,N-dimethylacrylamide), 2-methocyethyl (meth)acrylate, 2-aminoethyl (meth)acrylate, polyethylene glycol (PEG) (meth)acrylate in which the PEG group has a molar mass ranging from 400 to 10 000 g/mol, and mixtures thereof.

The elastomer block B may consist of an alkyl(meth)acrylate monomer. Alternatively, block B may comprise at least 95% (e.g. 95 to 99.9%) of alkyl (meth)acrylate, and 5% or less (e.g. 0.1 to 5%) of another monomer differing from alkyl (meth)acrylate, by weight of the total weight of block B.

The alkyl (meth)acrylate may be chosen from the group consisting of ethyl acrylate (Tg=−24° C.), butyl acrylate (−54° C.), 2-ethylhexyl acrylate (−85° C.), hydroxyethyl acrylate (−15° C.), 2-ethylhexyl methacrylate (−10° C.), and mixtures thereof; preferably the alkyl (meth)acrylate is butyl acrylate.

The other monomer differing from alkyl (meth)acrylate may be chosen from the group consisting of butadiene, isoprene, styrene, vinylnaphthalene, a cyclosiloxane monomer, vinylpyridine and derivatives thereof (e.g. a-methylstyrene or tert-butylstyrene).

The B-M diblock copolymer may have a number average molecular weight of between 10,000 and 500,000 g/mol, preferably between 20,000 and 200,000 g/mol.

The diblock B-M copolymer may comprise a weight fraction (by weight of the total weight of the copolymer) of between 5 and 95%, preferably between 15 and 85%, of block M; and between 5 and 95%, preferably 15 and 85% of block B.

For the triblock M-B-M copolymer, the two M blocks consist of the same monomers (or co-monomers) as block M in the diblock B-M copolymer such as described above. These two blocks M may be the same or different. For example, these two blocks M may differ in molar mass but may consist of the same monomers.

Block B consist of the same monomers (or co-monomers) as block B in the diblock B-M copolymer such as described above.

The triblock M-B-M copolymer may have a number average molar mass comprised between 10,000 g/mol and 500,000 g/mol, preferably comprised between 20,000 g/mol and 200,000 g/mol.

The triblock M-B-M copolymer may comprise a weight fraction (by weight of the total weight of the copolymer) of between 10 and 80%, preferably between 15 and 70%, more preferably between 40 and 60% of blocks M; and between 20 and 90%, preferably between 30 and 85%, more preferably between 40 and 60% of block B. One example of a triblock M-B-M copolymer is a polymethylmethacrylate-poly(styrene-co-butylacrylate)-polymethylmethacrylate block copolymer.

The block copolymers may be produced by controlled radical polymerization (CRP), for example following the methods described in PCT applications WO 96/24620 A and WO 00/71501 A1, or by anionic polymerization.

At least one among the blocks M and B may be functionalized by one or more functions chosen from the group consisting of acid, amine, amide, epoxy, thiol functions, quaternary ammonium groups, chlorinated groups, and fluorinated groups.

The block copolymers are commercially available under the trade name Nanostrength® Arkema.

(Meth)acrylate monomers

The composition comprises at least one (meth)acrylate monomer having a glass transition temperature (Tg) of at least 85° C.

The composition may comprise from 45 to 75%, preferably 45 to 70%, more preferably 45 to 65% of at least one (meth)acrylate monomer having a glass transition temperature of at least 85° C., by weight of the total weight of the composition. For example, the composition may comprise from 45 to 46%, alternatively 46 to 47%, alternatively 47 to 48%, alternatively 48 to 49%, alternatively 49 to 50%, alternatively 50 to 51%, alternatively 51 to 52%, alternatively 52 to 53%, alternatively 53 to 54%, alternatively 54 to 55%, alternatively 55 to 56%, alternatively 56 to 57%, alternatively 57 to 58%, alternatively 58 to 59%, alternatively 59 to 60%, alternatively 60 to 61%, alternatively 61 to 62%, alternatively 62 to 63%, alternatively 63 to 64%, alternatively 64 to 65%, alternatively 65 to 66%, alternatively 66 to 67%, alternatively 67 to 68%, alternatively 68 to 69%, alternatively 69 to 70%, alternatively 70 to 71%, alternatively 71 to 72%, alternatively 72 to 73%, alternatively 73 to 74%, alternatively 74 to 75% of at least one (meth)acrylate monomer having a glass transition temperature of at least 85° C., by weight of the total weight of the composition.

The (meth)acrylate monomer having a glass transition temperature of at least 85° C. may be chosen from the group consisting of methyl methacrylate, tert-butyl methacrylate, phenyl-methacrylate, isobornyl methacrylate, isobornyl acrylate, cyclohexyl methacrylate, 4-ter-butylcyclohexyl methacrylate, dihydrodicyclopentadienyl acrylate and mixtures thereof; preferably the (meth)acrylate monomer having a glass transition temperature of at least 85° C. is methyl methacrylate.

### Alkoxysilane (Meth)Acrylate Monomers

The composition comprises at least one alkoxysilane (meth)acrylate monomer.

The composition may comprise from 2 to 15%, preferably 3 to 10%, more preferably 4 to 6% of at least one alkoxysilane(meth)acrylate monomer by weight of the total weight of the composition. For example, the composition may comprise from 2 to 3%, alternatively 3 to 4%, alternatively 4 to 5%, alternatively 5 to 6%, alternatively 6 to 7%, alternatively 7 to 8%, alternatively 8 to 9%, alternatively 9 to 10%, alternatively 10 to 11%, alternatively 11 to 12%, alternatively 12 to 13%, alternatively 13 to 14%, alternatively 14 to 15% of at least one alkoxysilane (meth)acrylate by weight of the total weight of the composition.

The alkoxysilane (meth)acrylate monomer, including the alkyl alkoxysilane (meth)acrylate, may be chosen from the group consisting of trialkoxysilane (meth)acrylate monomers; preferably the trimethoxysilane (meth)acrylate monomers; preferably the alkoxysilane (meth)acrylate monomer is chosen from the group consisting of 3-(trimethoxysilyl)propyl acrylate, 3-(trimethoxysilyl)propyl methacrylate, trimethoxysilyl acrylate, trimethoxysilyl acrylate and mixtures thereof; preferably the alkoxysilane (meth)acrylate monomer is trimethoxysilyl acrylate.

Trimethoxysilane acrylate is commercially available under the trade name Silquest®A174 by Momentive®.

### Photoinitiator

The composition comprises at least one photoinitiator. Any compound able to initiate photopolymerization of the adhesive composition, in particular any compound able to initiate radical polymerization of the monomers and/or urethane (meth)acrylate oligomers by ultraviolet radiation (UV) or visible light, to obtain the adhesive, may be used.

The composition may comprise from 0.1 to 5%, preferably 0.5 to 4%, more preferably 1 to 3% of at least one photoinitiator by weight of the total weight of the composition. For example, the composition may comprise 0.1 to 1%, alternatively 1 to 2%, alternatively 2 to 3%, alternatively 3 to 4%, alternatively 4 to 5% of at least one photoinitiator by weight of the total weight of the composition.

The photoinitiator may be chosen from the group consisting of phenylbis(2,4,6-trimethylbenzoyl)phosphine oxide, triethylbenzoyl-diphenylphosphine oxide, thioxanthen-9-one, 4,4-bis(diethylamino)benzophenone, 9,10-phenanthrenequinone, benzoyltrimethylgermane, dibenzoyldiethylgermane, bis-(4-methoxybenzoyl)diethylgermanium and mixtures thereof; preferably phenylbis(2,4,6-trimethylbenzoyl)phosphine oxide. For example, a mixture may comprise benzophenone, a-hydroxyketone and triethylbenzoyl-diphenylphosphine oxide. Another mixture may comprise for example benzoyltrimethylgermane, dibenzoyldiethylgermane and bis-(4-methoxybenzoyl)diethylgermanium.

Phenylbis(2,4,6-trimethylbenzoyl)phosphine oxide is commercially available under the trade name Irgacure® 819 by Ciba® Specialty Chemicals. The mixture comprising benzophenone, a-hydroxyketone and triethylbenzoyl-diphenylphosphine oxide is commercially available under the trade name Esacure® KTO 46 by Lehvoss.

### Other (Meth)Acrylate Monomer

The composition may comprise at least one (meth)acrylate monomer having a glass transition temperature (Tg) lower than 0° C. In this embodiment, the composition comprises the mixture of a (meth)acrylate monomer having a glass transition temperature of at least 85° C. and a (meth)acrylate monomer having a glass transition temperature lower than 0° C.

The composition may comprise from 0 to 5% of at least one (meth)acrylate monomer having a glass transition temperature lower than 0° C., by weight of the total weight of the composition. If included, the composition may comprise from 0.1 to 5% of at least one (meth)acrylate monomer having a glass transition temperature lower than 0° C. For example, the composition may comprise from 0 to 1% (0.1 to 1%), alternatively 1 to 2%, alternatively 2 to 3%, alternatively 3 to 4%, alternatively 4 to 5% of at least one (meth)acrylate monomer having a glass transition temperature lower than 0° C., by weight of the total weight of the composition.

The (meth)acrylate monomer having a glass transition temperature lower than 0° C. may be chosen from the group consisting of butyl acrylate, ethyl acrylate, propyl acrylate, hexyl acrylate, octyl acrylate, dodecyl acrylate, isopropyl acrylate, isobutyl acrylate, isodecyl acrylate, 2-ethylhexyl acrylate, 2-propylheptyl acrylate, isodecyl methacrylate, dodecyl methacrylate, 2-hydroxyethyl acrylate, and mixtures thereof; preferably butyl acrylate.

Alternatively, the composition may be substantially free of (meth)acrylate monomers having a glass transition temperature (Tg) lower than 0° C.

### Methacrylic Acid

The composition may comprise a methacrylic acid monomer.

The composition may comprise from 0 to 20% of methacrylic acid by weight of the total weight of the composition. If included, the composition comprises from 1 to 16%, preferably 3 to 12% of methacrylic acid by weight of the total weight of the composition. For example, the composition may comprise from 0 to 1%, alternatively 1 to 2%, alternatively 2 to 3%, alternatively 3 to 4%, alternatively 4 to 5%, alternatively 5 to 6%, alternatively 6 to 7%, alternatively 7 to 8%, alternatively 8 to 9%, alternatively 9 to 10%, alternatively 10 to 11%, alternatively 11 to 12%, alternatively 12 to 13%, alternatively 13 to 14%, alternatively 14 to 15%, alternatively 15 to 16%, alternatively 16 to 17%, alternatively 17 to 18%, alternatively 18 to 19%, alternatively 19 to 20% of methacrylic acid by weight of the total weight of the composition.

### Urethane (Meth)Acrylate Oligomer

The composition may comprise at least one urethane (meth)acrylate oligomer.

The composition may comprise from 0 to 7% of at least one urethane (meth)acrylate oligomer by weight of the total weight of the composition. If included, the composition comprises from 0.1 to 7%, preferably 3 to 6% of at least one urethane (meth)acrylate oligomer by weight of the total weight of the composition. For example, the composition may comprise from 0 to 1%, alternatively 1 to 2%, alternatively 2 to 3%, alternatively 3 to 4%, alternatively 4 to 5%, alternatively 5 to 6%, alternatively 6 to 7%, alternatively 7 to 8%, alternatively 8 to 9%, alternatively 9 to 10% of at least one urethane (meth)acrylate monomer by weight of the total weight of the composition.

The urethane (meth)acrylate oligomer may be chosen from among aliphatic urethane diacrylate oligomers, preferably the urethane (meth)acrylate oligomer is aliphatic urethane diacrylate.

The composition may further comprise at least one monofunctional reactive diluent.

The composition may comprise from 0 to 0.7% of at least one monofunctional reactive diluent by weight of the total weight of the composition. If included, the composition comprises from 0.1 to 0.7%, preferably 0.3 to 0.7% of at least one monofunctional reactive diluent by weight of the total weight of the composition.

The monofunctional reactive diluent may be 2-(2-ethoxy-ethoxy) ethyl acrylate. The mixture of a urethane (meth)acrylate monomer and a monofunctional reactive diluent consists of about 90% aliphatic urethane diacrylate and about 10% of 2-(2-ethoxy-ethoxy) ethyl acrylate by weight of the total weight of the mixture is commercially available under the trade name CN966H90® by Sartomer.

### Viscosity

The photopolymerizable adhesive composition is preferably a liquid composition. The composition may have viscosity of 100 to 10,000 mPa·s, preferably of 500 to 5,000 mPa·s, more preferably 1,000 to 2,500 mPa·s. Viscosity may be measured according to standard NF EN 12092 “Adhesives—Determination of viscosity” using a Brookfield DVIII Ultra viscosimeter (spindle: SC4-27, rotation: 20 rpm, temperature: 25° C.).

The composition has a glass transition temperature preferably of at least 85° C., preferably at least 90° C., more preferably at least 100° C.

In some particular embodiments, the composition, by weight relative to the total weight of the composition, may comprise (alternatively may consist of):
20 to 35%, preferably 25 to 30% of at least one block copolymer;
45 to 75%, preferably 45 to 70%, more preferably 45 to 65% of at least one (meth)acrylate monomer having a glass transition temperature of at least 85° C.;
2 to 15%, preferably 3 to 10%, more preferably 4 to 6% of at least one alkoxysilane (meth)acrylate monomer;
0.1 to 5%, preferably 0.5 to 4 00 more preferably 1 to 3% of at least one photoinitiator;
0 to 5%, preferably 0.1 to 5% of at least one (meth)acrylate monomer having a glass transition temperature lower than 0° C.;
0 to 20 00 preferably 1 to 16%, more preferably 3 to 12% of methacrylic acid;
0 to 7%, preferably 0.1 to 7%, more preferably 3 to 6% of at least one urethane (meth)acrylate oligomer; and
0 to 0.7%, preferably 0.1 to 0.7%, more preferably 0.3 to 0.7% of at least one monofunctional reactive diluent.

In some particular embodiments, the composition may comprise (alternatively may consist of):
at least one block copolymer; preferably at least one (meth)acrylic block copolymer; preferably a (meth)acrylic block copolymer having a triblock structure M-B-M;
at least one (meth)acrylate monomer having a glass transition temperature of at least 85° C.; preferably a monomer chosen from the group consisting of methyl methacrylate, tert-butyl methacrylate, phenyl-methacrylate, isobornyl methacrylate, isobornyl acrylate, cyclohexyl methacrylate, 4-ter-butylcyclohexyl methacrylate, dihydrodicyclopentadienyl acrylate, and mixtures thereof; preferably the monomer being methyl methacrylate;
at least one alkoxysilane (meth)acrylate monomer; preferably a monomer chosen from the group consisting of trialkoxysilane (meth)acrylate monomers; preferably trimethoxysilane (meth)acrylate monomers; preferably 3-(trimethoxysilyl)propyl acrylate, 3-(trimethoxysilyl)propyl methacrylate; trimethoxysilyl acrylate, trimethoxysilyl acrylate and mixtures thereof; preferably the monomer being trimethoxysilyl acrylate;
at least one photoinitiator; preferably a photoinitiator chosen from the group consisting of phenylbis(2,4,6-trimethylbenzoyl)phosphine oxide, triethylbenzoyl-diphenylphosphine oxide, thioxanthen-9-one, 4,4-bis(diethylamino)benzophenone, 9,10-phenanthrenequinone, benzoyltrimethylgermane, dibenzoyldiethylgermane, bis-(4-methoxybenzoyl)diethylgermanium and mixtures thereof; preferably the photoinitiator being phenylbis(2,4,6-trimethylbenzoyl)phosphine oxide;
optionally, at least one (meth)acrylate monomer having a glass transition temperature lower than 0° C.; preferably a monomer chosen from the group consisting of butyl acrylate, ethyl acrylate, propyl acrylate, hexyl acrylate, octyl acrylate, dodecyl acrylate, isopropyl acrylate, isobutyl acrylate, isodecyl acrylate, 2-ethylhexyl acrylate, 2-propylheptyl acrylate, isodecyl methacrylate, dodecyl methacrylate, 2-hydroxyethyl acrylate, and mixtures thereof; preferably the monomer being butyl acrylate;
optionally, a methacrylic acid monomer;
optionally, at least one urethane (meth)acrylate monomer; preferably an oligomer chosen from among aliphatic urethane diacrylate oligomers; preferably an oligomer being an aliphatic urethane diacrylate oligomer;
optionally, at least one monofunctional reactive diluent; preferably the diluent being 2-(2-ethoxy-ethoxy) ethyl acrylate.

### One-Component Composition

The composition may be a one-component composition i.e., a ready-to-use composition. In contrast, the composition is preferably not a multi-component composition i.e., a kit comprising at least two components packaged separately, said components intended to be mixed together extemporaneously just before application of the resulting composition.

A one-component composition does not need to be prepared in the form of at least two separate components to be mixed just before use to prevent early polymerization. The one-component composition comprises at least one photoinitiator allowing polymerization to be initiated as soon as the composition is exposed to light radiation in particular ultraviolet radiation (UV). To prevent any early or undue polymerization, the composition must not be exposed to light.

### Adhesive Product

In a second aspect, the present invention comprises an adhesive product.

The adhesive product comprises the photopolymerizable adhesive composition such as described above, and an opaque container in which it is contained. By “opaque container”, it is meant a container of which the walls do not allow the passing of light likely to activate the photoinitiator, in particular visible light and ultraviolet radiation (less than 600 nm).

The opaque container may be a container able to contain the composition and to preserve the properties thereof, in particular adhesive properties. The use of an opaque container prevents exposure of the composition to light (in particular to ultraviolet radiation) before use i.e. during storage and transport and thereby avoids any early or untimely polymerization.

The container may be chosen for example from the group comprising a bottle or tube.

### Adhesive

In a third aspect, the present invention relates to an adhesive, in particular an adhesive obtained from the photopolymerizable adhesive composition described above. By “adhesive” or “photopolymerized adhesive composition”, it is meant the adhesive layer obtained by applying the photopolymerizable adhesive composition, photopolymerization thereof and optionally forming of the adhesive thus obtained.

The adhesive is obtained with the method comprising the following steps:
applying the photopolymerizable adhesive composition such as described above to at least one barrier layer and/or electronic or optoelectronic device;
photopolymerizing the applied composition to obtain a polymerized adhesive; and
optionally forming the polymerized adhesive.

The adhesive may be in the form of a film.

The application of the composition may be performed using a conventional application technique, for example the following techniques: slot-die coating, deep coating, inkjet printing, spin coating, spray coating or by doctor blade.

Photopolymerization of the composition may be performed by exposure to ultraviolet radiation (UV) and visible light, in particular with the use of a UV lamp emitting in a range allowing activation of the photoinitiator without being absorbed by the barrier layer. A suitable UV lamp for example may be a UV source of the type UV LED system Delolux® 035. Photopolymerization may be carried out for between 1 and 10 min.

Optional forming of the adhesive may be carried out for example by thermoforming process.

The adhesive may have a thickness of 10 to 200 μm, preferably 10 to 100 μm, more preferably 10 to 30 μm.

The adhesive has a certain number of advantages, in particular for use at a temperature of at least 70° C., preferably at least 85° C., for example when the electronic or optoelectronic device is a photovoltaic cell or when the device must meet temperature test standards (e.g., automotive applications).

The adhesive preferably has satisfactory adhesive properties, in particular to allow satisfactory cohesion between the electronic or optoelectronic device and the barrier layers, even for flexible modules.

The adhesive preferably has satisfactory optical properties, in particular satisfactory transparency, in particular to allow transmittance of light waves toward the electronic or optoelectronic device and/or to limit diffraction thereof, in particular when the device is a photovoltaic cell. The adhesive may have transparency of 90% for transmittance at between 400 and 800 nm. Transparency may be measured by UV-visible transmittance spectrometry.

The adhesive preferably has satisfactory electrical properties, in particular satisfactory electrical insulation properties, in particular to prevent short-circuiting inside the module. Electrical insulation properties may be measured with standard ASTM D149.

The adhesive preferably has satisfactory strength, in particular against ageing under ultraviolet radiation, abrasion and/or impacts.

The adhesive preferably has satisfactory barrier properties, in particular water and oxygen (air) barrier properties. Barrier properties may be measured according to standard ASTM F 1249 with a water vapour transmission rate of less than 5 g.⁻²·j⁻¹, preferably less than 2 g.⁻²·j⁻¹, for a thickness of 1 mm at a temperature of 38° C. and relative humidity of 85%.

The adhesive preferably has satisfactory elastic properties. Elastic properties and in particular flexibility may be measured using a flexural tester with cylindrical mandrel using the three-point or four-point bending test method, or by tensile strength measurements.

### Electronic or Optoelectronic Module

In a fourth aspect, the present invention relates to a module, preferably a flexible module. The module corresponds to an encapsulated electronic or optoelectronic device.

The module may be obtained by superimposing ad assembling a series of layers.

The series of layers may comprise in this order:
first barrier layer;
first adhesive such as described above or obtained from the photopolymerizable adhesive composition described above;
electronic or optoelectronic device;
second adhesive such as described above or obtained from the photopolymerizable adhesive composition described above; and
second barrier layer.

The electronic or optoelectronic device may itself comprise a semiconductor layer deposited on a supporting substrate.

This series of layers may also comprise additional layers, in particular layers intercalated between a barrier layer and an adhesive, e.g. an additional layer improving adhesion between the inner surface of a barrier layer and a layer of adhesive composition, surface treatment of the barrier layer, etc.

In the module thus obtained, the electronic or optoelectronic device is preferably coated with two adhesives superimposed on their periphery to form a seal. Coating of the electronic or optoelectronic device with the adhesives and encapsulation thereof between the two barrier layers insulates the device from the environment.

The module obtained has satisfactory properties allowing the limiting and even preventing both of orthogonal permeation and of lateral permeation, whilst maintaining the flexibility properties of the electronic or optoelectronic device.

The module may have a total thickness of 50 to 500 μm, preferably 50 to 300 μm, more preferably 50 to 150 μm.

The electronic or optoelectronic devices may be chosen from among rigid, flexible devices or combinations thereof; preferably the devices are flexible devices; preferably the devices are chosen from among organic light-emitting diodes, organic photovoltaic cells, organic transistors, or organic sensors.

In one particular embodiment, the photovoltaic cells are devices of perovskite type. So-called halide perovskite material may comprise a metal in its crystalline structure (e.g., lead or tin), organic and inorganic cations (e.g., caesium, formamidinium and/or ammonium), halide anions (e.g., boron or iodine). Devices of perovskite type are particularly suitable for photovoltaic applications. However, devices of perovskite type may exhibit problems of stability over time on account their sensitivity to the atmosphere in particular to water vapour.

The barrier layers may be the same or different.

The barrier layers may be monolayer or multilayer.

The barrier layers may be flexible or rigid, preferably flexible.

The module may have an orientation e.g. in that it comprises a lower and upper barrier layer known as a backsheet and frontsheet. The frontsheet is preferably transparent and the backsheet is preferably opaque.

According to the electronic or optoelectronic device used and the desired characteristics and properties of the module, the barrier layers may have specific properties.

A barrier layer may be a polymer.

A barrier layer may be inorganic.

A polymer barrier layer may comprise at least one fluorinated polymer layer obtained from at least one fluorinated polymer e.g. polyvinyl fluoride (PVF), polyvinylidene fluoride (PVDF), and mixture thereof.

A polymer barrier layer may comprise at least one polymer layer obtained from polyethylene terephthalate (PET) (or PET layer).

A polymer barrier layer may comprise at least one polymer layer obtained from ethylene-vinyl acetate (EVA) (or EVA layer).

A monolayer barrier layer may comprise a layer chosen from among a fluorinated polymer layer, PET layer or EVA layer. A multilayer barrier layer may comprise at least two layers, preferably three layers, chosen from among a fluorinated polymer layer, PET layer, EVA layer or combinations thereof. For example, a triple layer barrier layer may comprise a fluorinated polymer layer/PET layer/fluorinated polymer layer, or fluorinated polymer layer/PET layer/EVA layer.

The fluorinated polymer layer, PET layer and EVA layer and combinations thereof, and the monolayer or multilayer barrier layers obtained therefrom, are particularly suitable for use as frontsheet or backsheet.

A barrier layer may comprise at least one glass layer.

A barrier layer may comprise at least one polymer layer obtained from poly(methyl methacrylate) (PMMA) (or PMMA layer).

The glass layer or PMMA layer are particularly suitable for use as frontsheet or backsheet.

A flexible barrier layer particularly suitable for encapsulating flexible electronic or optoelectronic devices, in particular organic photovoltaic cells e.g. devices of perovskite type, is commercially available under the trade name 3M Ultra-Barrier Solar Film by 3M®, This barrier film is a laminated multilayer film comprising a PET film, an inorganic barrier layer, a pressure sensitive adhesive film (PSA), and fluoro-polymer film.

Method for obtaining the electronic or optoelectronic module

In a fifth aspect, the present invention relates to a method for obtaining the module such as described above, the method comprising the following steps:
providing an electronic or optoelectronic device;
providing a photopolymerizable adhesive composition such as described above;
providing a first barrier layer;
providing a second barrier layer;
applying layers of photopolymerizable adhesive composition to the surface of the device and/or to the respective inner surfaces of the first and second barrier layers;
laminating the device and layers or photopolymerizable adhesive composition between the respective inner surfaces of the first and second barrier layers; and
photopolymerizing the layers of photopolymerizable adhesive composition.

The method may also comprise an irradiation step with ultraviolet-ozone radiation of the first barrier layer and/or second barrier layer before the application step and/or laminating step.

In one particular embodiment, the rigid modules are obtained with a vacuum laminating technique under temperature control, known as “sheet-to-sheet” lamination.

In one particular embodiment, the flexible modules are obtained with a “roll-to-roll” technique such as described for example in the article by S. Razza et al: “Research Update: Large-area deposition, coating, printing, and processing techniques for the upscaling of perovskite solar cell technology”, APL Materials (2016) 4(9). This technique is particularly adapted for flexible electronic or optoelectronic devices; preferably the devices are chosen from among organic light-emitting diodes, organic photovoltaic cells, organic transistors, or organic sensors; preferably devices of perovskite type.

### Applications and Uses

In a sixth aspect, the present invention relates to the use of the photopolymerizable adhesive composition such as described above, and of the adhesive obtained therefrom such as described above, for the encapsulation of electronic or optoelectronic devices, in particular for the encapsulation of flexible electronic or optoelectronic devices e.g. for the encapsulation of organic photovoltaic devices, in particular devices of perovskite type.

### EXAMPLES

The following examples illustrate but do not limit the invention.

### List of Materials and Equipment

Block copolymer: Triblock M-B-M- copolymer (polymethylmethacrylate-poly(styrene-co-butylacrylate)-polymethylmethacrylate block copolymer (abbreviation: M-B-M):
(Meth)acrylate monomers having a glass transition temperature of at least 85° C.: methyl methacrylate (abbreviation: MAM).
Alkoxysilane (meth)acrylate monomers: trimethoxysilane acrylate (Silquest® by Momentive®) (abbreviation: A174).
Photoinitiators: phenylbis(2,4,6-trimethylbenzoyl)phosphine oxide (Irgacure®819 by Ciba® Specialty Chemicals (abbreviation: 1819), also available from Sigma-Aldrich.
(Meth)acrylate monomers having a glass transition temperature lower than 0° C.; butyl acrylate (abbreviation: ABu).
Methacrylic acid (abbreviation: AMA).
Urethane (meth)acrylate oligomers: aliphatic urethane diacrylate in 10% 2-(2-ethoxy-ethoxy) ethyl acrylate (CN966H90® by Sartomer) (abbreviation CN966).
Commercial composition: Delo® Katiobond® by Delo.
Light source: UV LED system Delolux® 03S.

### Modules to be Tested

The modules to be tested are routinely called test specimens.

PK layer: perovskite layer of formula Cs_{0.05}FA_{0.95}Pb(I_{0.88}Br_{0.12})₃ of surface area 4×4 cm (16 cm²).

Glass layer: layer of surface area 5×5 (25 cm²).

ITO layer: tin-doped indium oxide layer.

SnO₂ layer: tin dioxide layer.

The glass, ITO and/or SnO₂ layers form the supporting substrate as such.

Multilayer module 1: glass/ITO/SnO₂/PK.

Multilayer module 2: glass/ITO/PK/ITO.

The SnO₂ and/or PK layers were deposited by spin coating technique. The upper ITO layer (module 2) was deposited by physical vapour deposition.

The perovskite layers were deposited on the supporting substrate with an overhang of 5 mm between the edge of the substrate and the perovskite layer.

The modules were individually encapsulated between two glass barrier layers of thickness 1.2.mm with the photopolymerizable compositions to be tested.

### Test Methods

The thermal and gas-barrier properties of the tested modules were analysed by differential scanning calorimetry (DSC). Measurements were taken over three cooling-heating cycles ranging from −80 to 200° C. at a rate of 10° C. per minute. The glass transition temperature was measured at the third heating cycle with the half-height tangent method calculated at between 4° and 140° C.

The degradation rate (cm²/h) was determined in relation to degradation of a perovskite layer. Degradation of the tested modules was assessed with the following method: the test specimen described above was placed in a climate chamber at a temperature of 85° C. and relative humidity of 85% conforming to the test climate conditions for photovoltaic modules according to the method of standard IEC 61615, to determine an algorithmic parameter of degradation rate (cm²/h); cf. the article by E. Booker et al: “Perovskite test: A high throughput method to screen ambient encapsulation conditions”, Energy Technology (2020) 8(12). Photographic pictures of the test specimens were regularly taken e.g. every 48 h to evaluate ageing of the perovskite layers. The residual surface of the perovskite layers (thickness) was determined to calculate the degradation rate of these layers (cm²/h) from the linear regression of points between 12 cm² and 2 cm². Regions having a thickness of 180 nm or less were considered to be degraded regions (black regions, algorithmic analysis) and regions having a thickness greater than 180 nm were considered to be intact regions (grey regions, algorithmic analysis).

### Photopolymerizable Adhesive Compositions

The following photopolymerizable adhesive compositions were prepared (cf. Table 1, the proportions being expressed in weight percentage relative to the total weight of the photopolymerizable adhesive composition):

TABLE 1

| | M-B-M | MAM | A174 | ABu | AMA | CN966 | I819 |
|---|---|---|---|---|---|---|---|
| Ex. 1 | 29.21 | 53.55 | 4.87 | 0 | 4.87 | 4.87 | 2.63 |
| Ex. 2 | 20.45 | 62.31 | 4.87 | 0 | 4.87 | 4.87 | 2.63 |
| Ex3 | 34.08 | 48.68 | 4.87 | 0 | 4.87 | 4.87 | 2.63 |
| Ex4 | 29.21 | 53.55 | 4.87 | 0 | 9.74 | 0 | 2.63 |
| Ex5 | 25.32 | 53.55 | 4.87 | 3.89 | 4.87 | 4.87 | 2.63 |
| CExA | 29.21 | 37.48 | 4.87 | 16.07 | 4.87 | 4.87 | 2.63 |
| CExB | 29.21 | 44.98 | 4.87 | 8.57 | 4.87 | 4.87 | 2.63 |

The compositions CExA and CExB are comparative compositions.

### Test 1

At a first test, the degradation rate was tested of the multilayer modules 1 obtained with composition Ex1 (invention) and compositions CExA and CExB (comparative). Two series of tests were conducted with each composition.

These compositions differ in particular through the proportion of (meth)acrylate monomers having a glass transition temperature lower than 0° C. (here butyl acrylate), considering that they comprise an identical total proportion (53.55%) of (meth)acrylate monomers i.e. the mixture of monomers having a glass transition temperature of at least 85° C. and of (meth)acrylate monomers having a glass transition temperature lower than 0° C.

The glass transition temperatures of the compositions tested were the following: 62.6° C. for composition CExA, 75.7° C. for composition CExB and 94.14° C. for composition Ex1. Composition Ex5 (of the invention) has a glass transition temperature of 86.2° C.

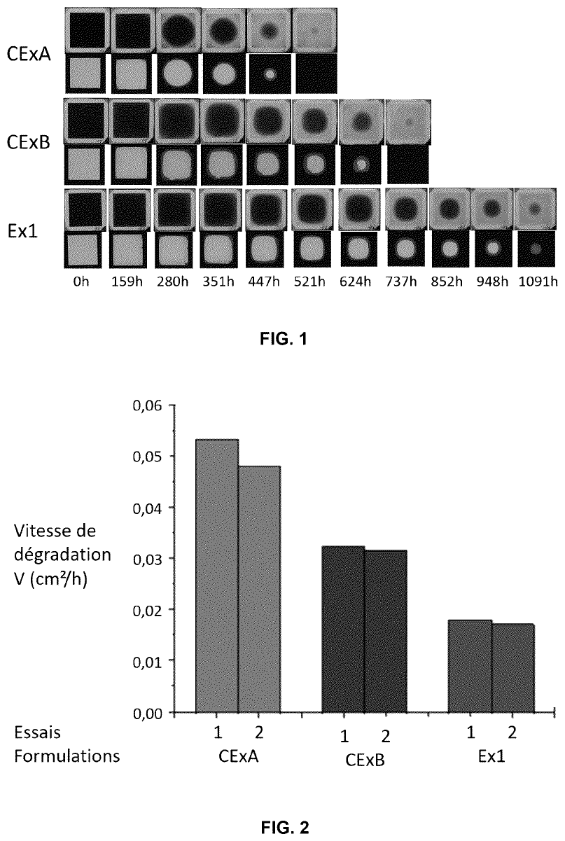

The tested modules were photographed at regular intervals. The pictures were taken at Oh, 159h, 280h, 351h, 447h, 521h, 624h, 737h, 852h, 948h and 1091h such as illustrated in FIG. 1 (the first lines correspond to the photographs and the second lines correspond to the images after computer analysis).

The degradation rate was correlated with a decrease in perovskite surface area over time, compared with the surface area of non-degraded perovskites (time=Oh), which allowed comparison of the impact of the different compositions on lateral permeation.

As illustrated in FIG. 2, unlike composition Ex1, this test shows that the comparative compositions with a high proportion of (meth)acrylate monomers having a glass transition temperature lower than 0° C. exhibit an insufficient glass transition temperature and high degradation rate, which corresponds to a high rate of lateral permeation.

In addition, the tested modules of the invention display a water vapour transmission rate of 2 g·mm·M⁻²·d⁻¹ according to the method described in the article by A. Kovrov et al: “Novel acrylic monomers for organic photovoltaics encapsulation”, Solar Energy Materials & Solar Cells (2020) 110210.

### Test 2

At a second test, the degradation rate of the multilayer modules 2 obtained with compositions Ex1-3 (invention) was tested. Two series of tests were conducted with each composition.

These compositions differ in particular through the proportion of block copolymer.

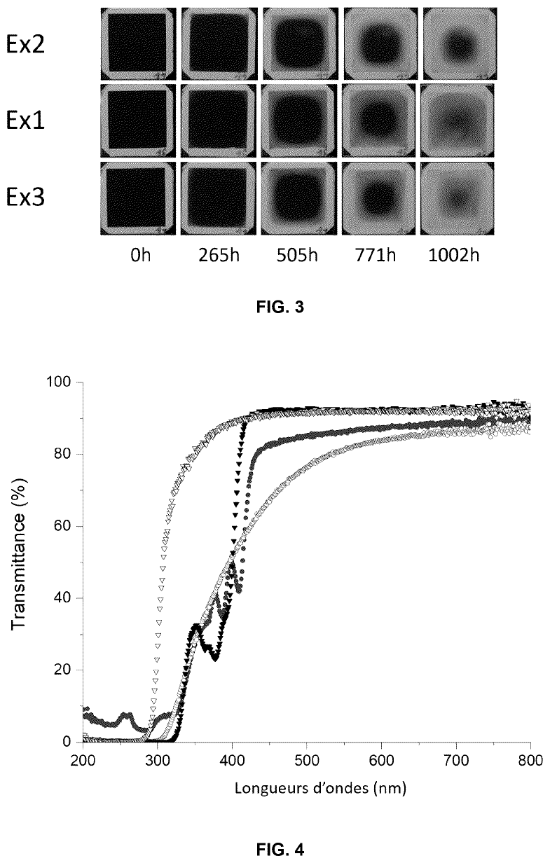

The tested modules were photographed at regular intervals. Pictures were taken at Oh, 265h, 505h, 771h, 1002h such as illustrated in FIG. 3 (each line corresponds to the photographs).

This test showed that there is no significant difference between the degradation rates of the three types of tested modules, confirming that these proportions of block copolymers do not negatively impact the gas-barrier properties of the adhesive compositions, or the glass transition temperature thereof, whilst maintaining satisfactory elastic (flexibility) properties.

### Test 3

At a third test, photo-ageing under continuous sunlight (solar spectrum: AM 1.5) of the adhesive layers obtained from composition Ex1 (invention) having a thickness of about 200 μm was tested in comparison with obtained layers of a commercially available composition (Delo® Katiobond® Ip655) having a thickness of 200 μm.

As illustrated in the graph in FIG. 4, the photo-ageing of the layers and possible yellowing was measured at between 0 and 1600h. The empty circles (white) correspond to data relating to the commercial composition at 1600h, the solid circles (black) correspond to data relating to the commercial composition at Oh; the empty triangles (white) correspond to data relating to composition Ex1 at 1600h, the solid triangles (black) correspond to data relating to composition Ex1 at Oh.

This test shows significant yellowing of the layer obtained with the commercially available composition, which necessarily leads to a decrease in the range of light transmittance, unlike the adhesive layers obtained from composition Ex1 (invention).

1. A photopolymerizable adhesive composition comprising by weight of total weight of the photopolymerizable adhesive composition:
20 to 35% of at least one block copolymer;
45 to 75% of at least one (meth)acrylic monomer having a glass transition temperature (Tg) of at least 85° C.;
2 to 15% of at least one alkoxysilane(meth)acrylic monomer; and
0.1 to 5% of at least one photoinitiator.

2. The photopolymerizable adhesive composition according to claim 1, wherein the block copolymer is chosen from the group consisting of block copolymers having at least one block M and at least one block B;
said block M designating a block polymer comprising at least 50 weight % of methyl methacrylate; and
said block B designating an elastomer block polymer incompatible with block M, and having a glass transition temperature (Tg) lower than 20° C.

3. The photopolymerizable adhesive composition according to claim 1, wherein the (meth)acrylate monomer having a glass transition temperature of at least 85° C. is chosen from the group consisting of methyl methacrylate, tert-butyl methacrylate, phenyl-methacrylate, isopropyl methacrylate, isobornyl methacrylate, isobornyl acrylate, cyclohexyl methacrylate, 4-ter-butylcyclohexyl methacrylate, dihydrodicyclopentadienyl acrylate, and mixtures thereof.

4. The photopolymerizable adhesive composition according to claim 1, wherein the alkoxysilane (meth)acrylate monomer is chosen from the group consisting of trialkoxysilane (meth)acrylate monomers.

5. The photopolymerizable adhesive composition according to claim 1, further comprising at least one (meth)acrylate monomer having a glass transition temperature lower than 0° C., a methacrylic acid monomer, at least one urethane (meth)acrylate oligomer, at least one monofunctional reactive diluent, and mixtures thereof.

6. The photopolymerizable adhesive composition according to claim 5, wherein the (meth)acrylate monomer having a glass transition temperature lower than 0° C., if included, is chosen from the group consisting of butyl acrylate, ethyl acrylate, propyl acrylate, hexyl acrylate, octyl acrylate, dodecyl acrylate, isopropyl acrylate, isobutyl acrylate, isodecyl acrylate, 2-ethylhexyl acrylate, 2-propylheptyl acrylate, isodecyl methacrylate, dodecyl methacrylate, 2-hydroxyethyl acrylate, and mixtures thereof.

7. The photopolymerizable adhesive composition according to claim 1, in that it is a one-component composition.

8. The photopolymerizable adhesive composition according to claim 1, in that it has a glass transition temperature of at least 85° C.

9. An adhesive product comprising the photopolymerizable adhesive composition according to claim 1 and an opaque container in which it is contained.

10. An adhesive obtained with the method comprising the following steps:
applying the photopolymerizable adhesive composition according to claim 1 to at least one barrier layer and/or at least one electronic or optoelectronic device;
photopolymerizing the photopolymerizable adhesive composition applied, to obtain a polymerized adhesive; and
optionally forming the polymerized adhesive.

11. An electronic or optoelectronic module comprising the assembly of a series of layers comprising in this order:
first barrier layer;
first adhesive according to claim 10;
flexible electronic or optoelectronic device;
second adhesive according to claim 10; and
second barrier layer.

12. The electronic or optoelectronic module according to claim 11, wherein the flexible electronic or optoelectronic is chosen from among organic light-emitting diodes, organic photovoltaic cells, organic transistors, or organic sensors.

13. The electronic or optoelectronic module according to claim 11, wherein the flexible electronic or optoelectronic device is a device of perovskite type.

14. A method for obtaining the module according to claim 11, the method comprising the following steps:
providing an electronic or optoelectronic device;
providing a photopolymerizable adhesive composition according to comprising by weight of total weight of the photopolymerizable adhesive composition
20 to 35% of at least one block copolymer,
45 to 75% of at least one (meth)acrylic monomer having a glass transition temperature (T) of at least 85° C.,
2 to 15% of at least one alkoxysilane(meth)acrylic monomer, and
0.1 to 5% of at least one photoinitiator,
providing a first barrier layer;
providing a second barrier layer;
applying layers of photopolymerizable adhesive composition to the surface of the device and/or to the respective inner surfaces of the first and second barrier layers;
laminating the device and layers of photopolymerizable adhesive composition between the respective inner surfaces of the first and second barrier layers; and
photopolymerizing the layers of photopolymerizable adhesive composition.

15. Use of the photopolymerizable adhesive composition according to claim 1, for the encapsulation of flexible electronic or optoelectronic devices.

16. The photopolymerizable adhesive composition according to claim 1, wherein the at least one block copolymer is a (meth)acrylic block copolymer.

17. The photopolymerizable adhesive composition according to claim 1, in that it has a glass transition temperature of at least 100° C.

18. The photopolymerizable adhesive composition according to claim 1, in that it has a glass transition temperature of at least 100° C.

19. An electronic or optoelectronic module comprising the assembly of a series of layers comprising in this order:
first barrier layer;
first adhesive obtained from the photopolymerizable adhesive composition according to claim 1;
flexible electronic or optoelectronic device;
second adhesive obtained from the photopolymerizable adhesive composition according to claim 1; and
second barrier layer.

20. Use of the adhesive product according to claim 12, for the encapsulation of flexible electronic or optoelectronic devices.
